(19) United States
(12) Patent Application Publication
(10) Pub. No.: US 2002/0197509 A1
(43) Pub. Date: Dec. 26, 2002

(54) Ion-beam deposition process for manufacturing multi-layered attenuated phase shift photomask blanks

(76) Inventors: Peter Francis Carcia, Wilmington, DE (US); Laurent Dieu, Austin, TX (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/123,699

(22) Filed: Apr. 16, 2002

Related U.S. Application Data
(60) Provisional application No. 60/284,779, filed on Apr. 19, 2001.

(51) Int. Cl. C23C 16/00; B32B 9/04; B32B 9/00

(52) U.S. Cl. 428/689; 427/596; 427/248.1; 428/446; 428/698; 428/701; 428/699

(57) ABSTRACT

A single ion-beam deposition, or a dual ion-beam deposition process for fabricating attenuating phase shift photomask blanks capable of producing a phase shift of 180° and having an optical transmissivity of at least 0.001 at selected lithographic wavelengths <400 nm, comprising at least one layer of an optically transmitting and/or one layer of optically absorbing elemental or a compound material in a periodic or an aperiodic arrangement.

### FIELD OF INVENTION

This invention relates to manufacture of phase shift photomask blanks in photolithography, known in the art as the attenuating (embedded) type, using ion-beam deposition techniques. More specifically, this invention relates to attenuating phase-shift photomask blanks to be used with short wavelength (i.e., <400 nanometer) light, which attenuate and change the phase of transmitted light by 180° relative to the incident light. Additionally, this invention relates to photomask blanks with multi-layered coatings of simple or complex compounds of elemental materials on the blanks.

### TECHNICAL BACKGROUND

Microlithography is the process of transferring microscopic circuit patterns or images, usually through a photomask, on to a silicon wafer. In the production of integrated circuits for computer microprocessors and memory devices, the image of an electronic circuit is projected, usually with an electromagnetic wave source, through a mask or stencil on to a photosensitive layer or resist, applied to the silicon wafer. Commonly, the mask is a layer of “chrome” patterned with these circuit features on a transparent quartz substrate. Often referred to as a “binary” mask, a “chrome” mask transmits imaging radiation through the pattern where “chrome” has been removed. The radiation is blocked in regions where the “chrome” layer is present.

The electronics industry seeks to extend optical lithography for manufacture of high-density integrated circuits to critical dimensions of less than 100 nm. However, as the feature size decreases, resolution for imaging the minimum feature size on the wafer with a particular wavelength of light is limited by the diffraction of light. Therefore, shorter wavelength light, i.e. <400 nm is required for imaging finer features. Wavelengths targeted for succeeding generations of optical lithography include 248 nm (KrF laser wavelength), 193 nm (ArF laser wavelength), and 157 nm (F₂ laser wavelength) and lower. However, as the wavelength of the incident light decreases, the “depth of focus,”(DoF) or the tolerance of the process also decreases according to the following equation:

DoF=k₂(λ/NA²)

where k₂ is a constant for a given lithographic process, λ is the wavelength of the imaging light, and NA=sin θ is the numerical aperture of the projection lens. A larger DoF means that the process tolerance toward departures in wafer flatness and photoresist thickness uniformity is greater.

Resolution and DoF can be improved for a given wavelength with a phase shift photomask, which enhances the patterned contrast of small circuit features, by destructive optical interference. Therefore, as the minimum feature size in integrated circuits continues to shrink, the “phase-shift mask” becomes increasingly important in supplementing and extending the applications of traditional photolithography with “binary” masks. For example, in the attenuating (embedded) phase-shift mask, the electromagnetic radiation leaks through (attenuated) the unpatterned areas, while it is simultaneously phase-shifted 180°, instead of being blocked completely. Compared to “chrome” on quartz masks, phase-shift masks improve printing resolution of fine features and the depth of focus of the printing process.

The concept of a phase shift photomask and photomask blank that attenuates light and changes its phase was revealed by H. I. Smith in U.S. Pat. No. 4,890,309 (“Lithography Mask with a Pi-Phase Shifting Attenuator”). Two categories of known attenuating embedded phase shift photomask blanks include: (1) Cr-based photomask blanks containing Cr, Cr-oxide, Cr-carbide, Cr-nitride, Cr-fluoride or combinations thereof; and (2) SiO₂— or Si₃N₄-based photomask blanks, where SiO₂ or Si₃N₄ are doped with an opaque metal such as Mo to form a molybdenum silicon oxide, nitride, or an oxynitride.

Physical methods of thin film deposition are preferred to manufacture photomask blanks. These methods which are normally carried out in a vacuum chamber include glow discharge sputter deposition, cylindrical magnetron sputtering, planar magnetron sputtering, and ion beam deposition. A detailed description of each method can be found in the reference “Thin Film Processes,” Vossen and Kern, Editors, Academic Press NY, 1978). The method for fabricating thin film masks is almost universally planar magnetron sputtering.

The planar magnetron sputtering configuration consists of two parallel plate electrodes: one electrode holds the material to be deposited by sputtering and is called the cathode; while the second electrode or anode is where the substrate to be coated is placed. An electric potential, either RF or DC, applied between the negative cathode and positive anode in the presence of a gas (e.g., Ar) or mixture of gases (e.g., Ar+O₂) creates a plasma discharge (positively ionized gas species and negatively charged electrons) from which ions migrate and are accelerated to the cathode, where they sputter or deposit the target material on to the substrate. The presence of a magnetic field in the vicinity of the cathode (magnetron sputtering) intensifies the plasma density and consequently the rate of sputter deposition.

If the sputtering target is a metal such as chromium (Cr), sputtering with an inert gas such as Ar will produce metallic films of Cr on the substrate. When the discharge contains reactive gases, such as O₂, N₂, or CO₂, they combine with the target/or at the growing film surface to form a thin film oxide, nitride, carbide, or combination thereof, on the substrate.

Whether the mask is “binary” or phase-shifting, the materials that comprise the mask-film are usually chemically complex, and sometimes the chemistry is graded through the film thickness. Even a simple “chrome” mask is a chrome oxy-carbo-nitride (CrOxCyNz) composition that can be oxide rich at the film's top surface and more nitride-rich within the depth of the film. The chemistry of the top surface imparts antireflection character, while the chemical grading provides attractive anisotropic wet etch properties.

In the ion-beam deposition process (IBD), the plasma discharge is commonly contained in a separate chamber (ion “gun” or source) and ions are extracted and accelerated by an electric potential impressed on a series of grids at the “exit port” of the gun (other ion-extraction schemes without grids are also possible). The IBD process provides a cleaner process (fewer added particles) at the growing film surface, as compared to planar magnetron sputtering because the plasma, that traps and transports charged particles to the substrate, is confined to the gun and is not in the proximity of the growing film. Additionally, the IBD process operates at a total gas pressure at least ten times lower than traditional magnetron sputtering processes. (A typical pressure for IBD is ˜10⁻⁴ Torr.) This results in reduced levels of chemical contamination. For example, a nitride film with minimum or no oxide content can be deposited by the ion beam process. Furthermore, the IBD process has the ability to independently control the deposition flux and the reactive gas ion flux (current) and energy, which are coupled and not independently controllable in planar magnetron sputtering. The capability to grow oxides or nitrides or other chemical compounds with a separate ion gun that bombards the growing film with a low energy, but high flux of oxygen or nitrogen ions is unique to the IBD process and offers precise control of film chemistry and other film properties over a broad process range. Additionally, in dual ion beam deposition the angles between the target, the substrate, and the ion guns can be adjusted to optimize for film uniformity and film stress, whereas the geometry in magnetron sputtering is essentially constrained to a parallel plate electrode system.

While magnetron sputtering is extensively used in the electronics industry for reproducibly depositing all sorts of coatings, process control in sputtering plasmas is not accurate because the direction, energy, and flux of the ions incident on the growing film cannot be regulated. In ion beam deposition (IBD) proposed here, which is a novel alternative approach for fabricating masks with complex multi-layered chemistries, independent control of these deposition parameters is possible.

### SUMMARY OF THE INVENTION

This invention concerns a single ion-beam deposition process for preparing an attenuating phase shift photo mask blank capable of producing 180° phase shift at selected lithographic wavelengths less than 400 nanometer, the process essentially consisting of depositing at least one layer of optically transmitting material and at least one layer of optically absorbing material, or a combination thereof, on a substrate, by ion beam sputtering of a target or targets by ions from a group of gases.

This invention also concerns a dual ion-beam deposition process for preparing an attenuating phase shift photo mask blank capable of producing 180° phase shift at selected lithographic wavelengths less than 400 nanometer, the process comprising:

(a) depositing at least one layer of optically transmitting material and at least one layer of optically absorbing material or a combination thereof, on a substrate, by ion beam sputtering of at least one primary target by ions from a group of gases, and

(b) depositing at least one layer of optically transmitting material and optically absorbing material, or a combination thereof, on the said substrate using a secondary ion beam from an assist source of a group of gases wherein the layer or the layers are formed either directly, or by a combination of the gas ions from the assist source and the material deposited from the primary target on the substrate.

Furthermore, this invention concerns a dual ion-beam deposition process for preparing an attenuating phase shift photo mask blank capable of producing 180° phase shift at selected lithographic wavelengths less than 400 nanometer, the process comprising:

(a) depositing at least one layer of optically transmitting material and at least one layer of optically absorbing material or a combination thereof, on a substrate, by ion beam sputtering of a target or targets by ions from a group of gases, and

(b) bombarding the said substrate by a secondary ion beam from an assist source with ions from a reactive gas wherein the reactive gas is at least one gas selected from the group consisting of N₂, O₂, CO₂, N₂O, H₂O, NH₃, CF₄, CHF₃, F₂, CH₄, and C₂H₂.

### DETAILED DESCRIPTION OF THE INVENTION

Certain terms used herein are defined below.

In this invention, it is to be understood that the term “photomask” or the term “photomask blank” is used herein in the broadest sense to include both patterned and UN-patterned photomask blanks. The term “multilayers” is used to refer to photomask blanks comprised of layers of optically absorbing and/or optically transmitting films. The layers can be ultra-thin (1-2 monolayers) or much thicker. The relative layer thicknesses control optical properties. The layering can be periodic or aperiodic; layers can all have the same thickness, or they can each be different.

By “Depth of Focus” is meant the region above and below the plane of convergence of light projected from a projection lens, in which the defocus tolerance of the image is within the feature specification limit.

In addition to precise control of the phase-shift and optical transmission, an attenuating phase-shift mask must also stand up to harsh chemical cleaning cycles, be resistant to damage or change by the imaging radiation, have etch selectivity during patterning, and be capable of optical inspection to facilitate repair and validation of the patterned features. Multi-layered structures, or optical superlattices, comprising of optically absorbing and optically transmitting layers with precise thickness and flexibility of chemical makeup, can meet these requirements.

Single Ion Beam Deposition Process

A typical configuration for a single ion beam deposition process is shown in FIG. 2. It is understood that this system is in a chamber with atmospheric gases evacuated by vacuum pumps. In the single IBD process, an energized beam of ions (usually neutralized by an electron source) is directed from a deposition gun (1) to a target material (2), on a target holder (3). The target material (2) is sputtered when the bombarding ions have energy above a sputtering threshold energy for that specific material, typically ˜50 eV. The ions from the deposition-gun (1) are usually from an inert gas source such as He, Ne, Ar, Kr, Xe, although reactive gases such as O₂, N₂, CO₂, F₂, CH₃, or combinations thereof, can also be used. When these ions are from an inert gas source the target material (2) is sputtered and then deposits as a film on the substrate (4), shown on substrate holder (5). When these ions are from a reactive gas source they can combine with target material and the product of this chemical combination is what is sputtered and deposited as a film on the substrate.

Commonly, the bombarding ions should have energies of several hundred eV—a range of 200 eV to 10 KeV being preferred. The ion flux or current should be sufficiently high (>10¹³ ions/cm²/s) to maintain practical deposition rates (>0.1 nm/min). Typically, the process pressure is about 10⁻⁴ Torr, with a preferred range 10⁻³-10⁻⁵ Torr. The target material can be elemental, such as Si, Ti, Mo, Cr, or it can be multi-component such as MoₓSi_{y}, or it can be a compound such as SiO₂. The substrate can be positioned at a distance and orientation to the target that optimize film properties such as thickness, uniformity and minimum stress.

The process window or latitude for achieving one film property, for example, optical transparency, can be broadened with a dual ion-beam deposition process, as described below. Also, one particular film property can be changed independently of other sets of properties with the dual ion-beam process.

Dual Ion-Beam Deposition Process

The dual ion gun configuration is shown schematically in FIG. 1. In dual ion-beam deposition (DIBD), in addition to the process setup of single ion-beam deposition as described above, ions from a second or “assist” gun (6), usually neutralized by an electron source, can be directed at the growing film on the substrate (4). The ions from this gun can originate from a reactive gas source such as O₂, N₂, CO₂, F₂, or an inert gas such as Ne, Ar, Kr, Xe, or combinations thereof. The energy of ions from the assist gun is usually lower than from the deposition gun (1). The assist gun provides an adjustable flux of low energy ions that react with the sputtered atoms at the growing film surface. For example, sputtered Si atoms arriving at the substrate can react with nitrogen ions from the assist gun to form SiNₓ, where the ratio (x) of N to Si in the film can be controlled independently by adjusting the Si and nitrogen fluxes arriving at the growing film surface. It is also possible to use the assist gun in this configuration to directly deposit a thin film layer. For example, Druz et al. describe deposition of diamond-like carbon by ion beam deposition with CH₄ (“Ion beam deposition of diamond-like carbon from an RF inductively coupled CH₄-plasma source,” in Surface Coatings Technology 86-87, 1996, pp. 708-714).

For the “assist” ions, lower energy typically <500 eV are preferred, otherwise the ions may cause undesirable etching or removal of the film. In the extreme case of too high a removal rate, film growth is negligible because the removal rate exceeds the accumulation or growth rate. However, in some cases, higher assist energies may impart beneficial properties to the growing film, as for direct deposition of a film, or for reduced stress, in which case the preferred flux of these more energetic ions is usually required to be less than the flux of depositing atoms.

With the dual IBD process, any of these deposition operations can be combined to make more complicated structures. For example multilayers of SiNₓ and TiN_{y}, useful as an attenuating phase-shift mask, can be made by alternately depositing from elemental Si and Ti targets as the film is bombarded by reactive nitrogen ions from the assist gun. If the layers in a multilayer stack alternate from an oxide to a nitride as in SiO₂/Si₃N₄ multilayers, previously proposed as an attenuating phase-shift mask for application with uv radiation below 160 nm, dual ion beam deposition with a Si target offers significant advantage over traditional magnetron sputtering techniques. Whereas the assist source in dual IBD can be rapidly switched between O₂ and N₂ as Si atoms are deposited, reactive magnetron sputtering produces an oxide layer on the target surface that must be displaced before forming a nitride-rich surface for sputtering a nitride layer. Further, layering an oxide layer with a nitride layer can improve optical contrast at longer wavelength, important for inspection of the patterned photomask relative to quartz. Whereas the optical properties of metal oxides and nitrides may be equivalent at lithographic wavelengths, and thus optical transmission is the same, inspection tools that work at longer wavelength, e.g. 488 nm and 365 nm, where metal nitrides are more optically absorbing than their corresponding oxides, provide higher optical contrast there, an advantage for inspection and repair of patterned photomasks.

While it is possible to make films with complex chemistry such as Si₃N₄, with ion beam deposition using a single ion source the process is more restrictive than for dual ion beam deposition. Huang et al. in “Structure and composition studies for silicon nitride thin films deposited by single ion beam sputter deposition” Thin Solid Films 299 (1997) 104-109, demonstrated that films with Si₃N₄ properties only form when the beam voltage is in a narrow range about 800 V. Although a nitride target can be used at the outset with a single ion source to improve process latitude, the deposition rate can be impracticably slow and the purity of a nitride target is generally inferior to an elemental target. In dual ion beam sputtering the flux of nitrogen atoms from the assist source can be adjusted independently to match the flux of deposited Si atoms from the deposition ion source over a wide range of process conditions and at practical deposition rates.

This invention relates to the ion beam deposition process for depositing complex materials such as compounds, as distinct from elements for use in coating of lithographic masks. Examples of such materials include, but are not restricted to Si₃N₄, TiN, and multilayers of compound materials such as Si₃N₄/TiN, Ta₂05/SiO₂, SiO₂/TiN, Si₃N₄/SiO₂ or CrF₃/AIF₃.

This invention provides a novel technique for deposition of multilayer films for photomask blanks with a phase shift of about 180°, for particular incident wavelengths, and is thus especially useful for producing photomasks. Normally the film is deposited on a substrate. The substrate can be any mechanically stable material which is transparent to the wavelength of incident light used. The substrate can also be a reflective substrate. Substrates such as quartz,fused silica (glass), and CaF₂ are preferred for availability and cost.

This invention provides ion-beam deposition of the optically attenuating film in the form of a structure with optically absorbing layers and optically transmitting layers. The absorbing component is characterized by an extinction coefficient k>0.1 (preferably from 0.5 to 3.5) for wavelengths less than 400 nm, while the transmitting component is characterized by an extinction coefficient k<<1.0 for wavelengths less than 400 nm. The refractive index for wavelengths below 400 nm of the absorbing component is preferably from about 0.5 to about 3, and the refractive index of the transmitting component is preferably from about 1.2 to about 3.5.

The preferred ion-beam deposition materials can be classified in crystal chemistry architecture as belonging to the class of binary compounds: AX, AX₂, A₂X, and AₘX_{z}, or combinations thereof, where m and z are integers, and A represents a cation and X, an anion. Partial chemical substitution on both sites (A, X) is possible, including vacancies, consistent with maintaining chemical neutrality.

Preferably, this invention embodies ion-beam deposition of multilayers of SiNₓ/TiN_{y}, where x is nominally in the range from about 1.0 to about 1.3 and y is about 1.0. SiNₓ/TiN_{y} multilayers have been proposed as attenuating phase-shift masks for lithography with particular application at 248 nm and 193 nm. Previously, TiN/SiN phase-shift masks had been made by magnetron sputtering.

The optically transmitting components of the attenuating film can be selected from group of metal oxides, metal nitrides, and metal fluorides, and optically transmitting forms of carbon. The oxide based optically transmitting components of the attenuating film can be selected preferably from oxides with an optical bandgap energy of greater than about 3 eV such as Si, Al, Ge, Ta, Nb, Hf, and Zr. The nitride based optically transmitting components of the attenuating film can be selected preferably from nitride materials with an optical bandgap energy of greater than about 3 eV such as nitrides of Al, Si, B and C. The fluoride based optically transmitting components of the attenuating film can be selected preferably from materials such as fluorides with an optical bandgap energy of greater than about 3 eV such as fluorides of group 11 elements, or the lanthanides elements (atomic numbers 57-71). Optically transmitting carbon can be selected from essentially carbon, of which some fraction has the diamond structure, sometimes referred to as carbon with sp³ C—C bonding, and also known in the art as diamond-like carbon (DLC). Because of its wide range of optical properties, DLC can function either as the absorbing- or transmitting-layer. A combination of one or more of oxides, fluorides, nitrides, and DLC can also be deposited with the ion-beam deposition process.

The optically absorbing components of the attenuating film can be selected from the group of elemental metals, metal nitrides, oxides and a combination thereof. The oxide based optically absorbing components of the attenuating film can be selected preferably from materials with optical bandgap energy less than that of the transmitting component of the attenuating film, such as oxides of group IIIB, IVB, VB, and VIB. The nitride based optically absorbing components of the attenuating film can be selected preferably from materials with optical bandgap energy less than about 3 eV such as nitrides of group IIIB, IVB, VB, and VIB. A combination of one or more of metals, oxides, and nitrides can also be deposited with the ion-beam deposition process.

The optically absorbing layers of the film and the optically transmitting layers of the film can be ion-beam deposited in a periodic or an aperiodic arrangement. Preferably, the optically absorbing layers of the film and the optically transparent layers of the film are deposited in an alternating arrangement.

Optical Properties

The optical properties (index of refraction, “n” and extinction coefficient, “k”) were determined from variable angle spectroscopic ellipsometry at three incident angles from 186-800 nm, corresponding to an energy range of 1.5-6.65 eV, in combination with optical reflection and transmission data. From knowledge of the spectral dependence of optical properties, the film thickness corresponding to 180° phase shift, optical transmissivity, and reflectivity can be calculated. See generally, O. S. Heavens, Optical Properties of Thin Solid Films, pp 55-62, Dover, N.Y., 1991, incorporated herein by reference.

### BRIEF DESCRIPTION OF THE DRAWINGS

FIG. 1 is a schematic for the dual ion-beam deposition process.

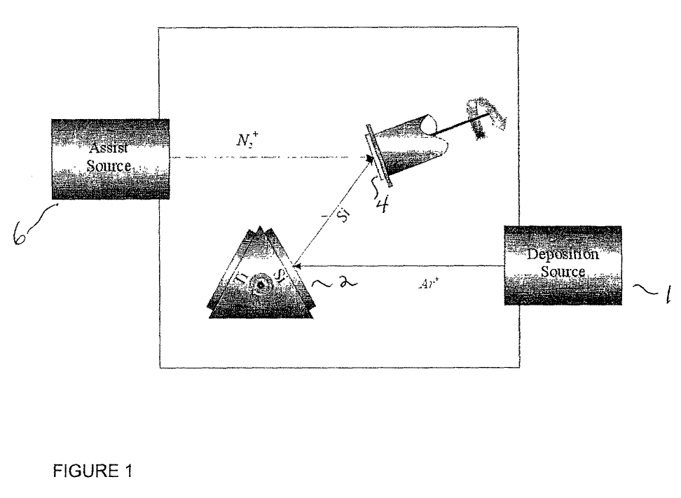

FIG. 2 is a schematic for the single ion-beam deposition process.

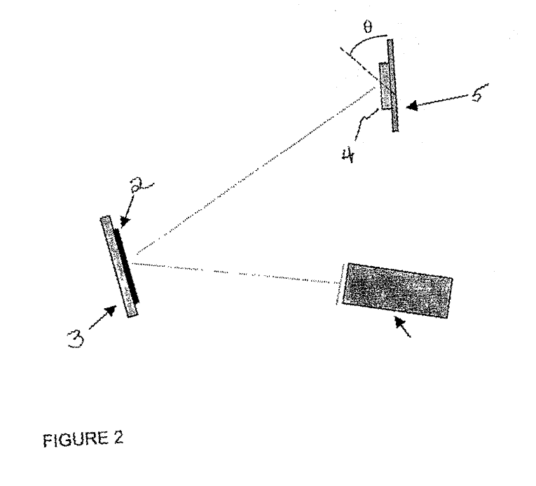

### EXAMPLES

### Examples 1 and 2

### SiN/TiN Multilayers

TiN/SiN multilayers were made by dual ion beam deposition in a Veeco IBD-210 apparatus from a Si and a Ti target. Alternate deposition from Ti and Si was carried out with the deposition source operating at a voltage of 750 V and a beam current of 160 mA. Ar gas of 6 sccm was delivered to the deposition source. Nitride formation in the growing film on the substrate was accomplished by bombarding the film with nitrogen ions from a separate ion assist source operating at 50 V and a current of 20 mA with nitrogen at 8 sccm delivered to the assist source. The substrate was 6×6-inch square quartz plate, with a thickness of ¼ inch. The following film compositions were synthesized by depositing alternately from Ti and Si targets;

(1) 15×(1.2 nm TiN+5.68 nm SiN) and

(2) 15×(1.45 nm TiN+5.43 nm SiN)

Formula (1) correspond to a multilayer structure of alternating TiN and SiN layers with thickness 1.2 nm (TiN) and 5.68 nm (SiN), respectively. This bilayer structure is then repeated 15 times, corresponding each to 15 individual layers of TiN, 1.2 nm thick, and SiN, 5.68 nm thick, corresponding to a total film thickness of 103.2 nm. The same interpretation applies to formula (2), using the TiN thickness of 1.45 nm and SiN thickness of 5.43 nm.

Both (1) and (2) were subsequently evaluated on a LaserTec MPM248 tool that directly measures optical transmission and phase-shift at 248 nm, an important lithographic wavelength in integrated circuit manufacture. The results were: (1) 180.4 degrees phase-shift with an optical transmission relative to quartz of 8.84%, and (2) 180.9 degrees phase-shift with an optical transmission relative to quartz of 6.5%. Both of these satisfy the optical requirements for the two commonly used phase-shift masks at 248 nm with nominal transmissions of 6% ±0.5 and 9% ±0.5.

### Examples 3, 4, 5

### SiON/TiON Multilayers

In these examples, TiON/SiON multilayers were made by dual ion beam deposition in a commercial tool (Veeco IBD-210) from an Si and a Ti target. Adding a small concentration of O₂ to the N₂ in the assist ion source had the effect of increasing the optical transmission for phase-shift mask application at 193 nm, since the optical absorption of the oxynitrides, especially SiON, is less than that for SiN. A higher transmission in a phase-shift mask can enhance the optical contrast or printing resolution. Multilayers of SiON/TiON were synthesized by alternately depositing from Ti and Si targets. The deposition ion beam source was operated at a voltage of 750 V and a beam current of 160 mA, while the assist source with N₂ and O₂ was operated at 50 V and a current of 20 mA. 6 sccm of Ar was delivered to the deposition source, while 6 sccm of N₂ and 2 sccm of a 10% O₂/90%N₂ mixture were delivered to the assist source. The substrate was a six-inch square quartz plate, ¼ inch thick. Three multilayer film compositions were synthesized, indicated as (3), (4), and (5). They were nominally:

(3.) 10×(0.5 nm TiON+7.0 nm SiON)

(4.) 10×(1.0 nm TiON+6.5 nm SiON)

(5.) 10×(1.5 nm TiON+6.0 nm SiON)

Using an optical spectrometer we measured the optical transmissions at 193 nm to be (3) 14.3%, (4) 8.7%, and (5) 6.0%. The transmissions are relative to air and they span the full range of transmissions required for practical phase-shift masks at 193 nm. An estimate of the phase-shift at 193 nm (from direct measurements at 248 nm) for these compositions ranges from 170-165 degrees, or about 2.27-2.20 degrees/nm. Thus, increasing the total film thickness of these multilayers by about 5 nm will give phase-shift of about 180 degrees for a range of calculated transmissions of 12.7% to 5%, useful for phase-shift mask application at 193 nm. From depth profiling (sputtering with Ar ions) of oxynitride films combined with X-ray photoelectron spectroscopic analysis of core electron energies, we determined the chemical composition of the individual layers to be Ti_{0.48}O_{0.12}N_{0.40} and Si₃N₄O_{0.08}N_{0.44}.

While it is possible to make films with complex chemistry, such as Si₃N₄, with ion beam deposition using a single ion source, the process is more restrictive than for dual ion beam deposition. Huang et al. in “Structure and composition studies for silicon nitride thin films deposited by single ion beam sputter deposition” Thin Solid Films 299 (1997) 104-109, demonstrated that films with Si₃N₄ properties only form when the beam voltage is in a narrow range about 800 V. Although a nitride target can be used at the outset with a single ion source to improve process latitude, the deposition rate can be impracticably slow and the purity of a nitride target is generally inferior to an elemental target. In dual ion beam sputtering the flux of nitrogen atoms from the assist source can be adjusted independently to match the flux of deposited Si atoms from the deposition ion source over a wide range of process conditions and at practical deposition rates.

One property of SiN that makes it attractive for mask applications at 193 nm is its relatively low optical absorption: specifically an extinction coefficient (k) of less than 0.45 and preferably less than 0.4 is needed in phase-shift mask applications. In the next four examples (Ex. 6, 7, 8, 9) a comparison is made of the optical properties of SiN films ion beam deposited from a single ion source and a dual ion beam source at low and high beam voltages. What is noteworthy is that only SiN deposited at low voltage from a single ion source has a low enough optical absorption (extinction coefficient), whereas low absorption can be achieved with the dual ion beam process at low and at high beam voltage, where higher deposition rate is possible.

### Example 6

### SiN by Single Ion Beam Source (700 V)

Silicon nitride films were deposited from an Si target on to quartz substrates, 1.5 in.×1.0 in.×0.25 in., using a 3 cm commercial (Commonwealth, Inc.) ion beam source, operating at 700 V beam voltage and 25 mA beam current. The deposition gases were 6 sccm N₂ and 1.37 sccm Ar. Two hours of deposition produced a film 580 A thick (4.83 A/min) with an optical transmission at 193 nm of 15.7%, corresponding to an extinction coefficient k=0.39, attractive for phase-shift mask application.

### Example 7

### SiN by Single Ion Beam Source (1300 V)

Silicon nitride films were deposited from a Si target on to quartz substrates, 1.5 in.×1.0 in.×0.25 in., using a 3 cm commercial (Commonwealth, Inc.) single ion beam source, operating at 1300 V beam voltage and 25 mA beam current. The deposition gases were 6 sccm N₂ and 1.37 sccm Ar. Two hours of deposition produced a film 875 A thick (7.29 A/min) with an optical transmission at 193 nm of only 1.4%, corresponding to an extinction coefficient k=0.71, too large for phase-shift mask application.

### Example 8

### SiN by Dual Ion-Beam Source (1500 V/50 V)

In this example silicon nitride films were made by dual ion beam deposition in a commercial tool (Veeco IBD-210) from a Si target. Deposition from Si was carried out with one ion beam deposition source operating at a voltage of 1500 V and a beam current of 200 mA, while nitriding the growing film with nitrogen ions from a second assist ion beam source, operating at 50 V and a current of 30 mA. Six sccm of Ar was delivered to the deposition source, while N₂ at 8 sccm was delivered to the assist source. The substrate was a six-inch square quartz plate, ¼ inch thick. A 15 min deposition produced a silicon nitride film 795 A thick (53 A/min) with an optical transmission at 193 nm of 8.2%, corresponding to an extinction coefficient k=0.428, attractive for phase-shift mask application.

### Example 9

### SiN by Dual Ion-Beam Source (600 V/50 V)

In this example silicon nitride films were made by dual ion beam deposition in a commercial tool (Veeco IBD-210) from a Si target. Deposition from Si was carried out with one ion beam deposition source operating at a voltage of 600 V and a beam current of 140 mA, while nitriding the growing film with nitrogen ions from a second assist ion beam source, operating at 50 V and a current of 15 mA. Six sccm of Ar was delivered to the deposition source, while N₂ at 8 sccm was delivered to the assist source. The substrate was a six-inch square quartz plate, ¼ inch thick. A 40 min deposition produced a silicon nitride film 1215 A thick (30.4 A/min) with an optical transmission at 193 nm of 3.7%, corresponding to an extinction coefficient k=0.406, attractive for phase-shift mask application.

Examples 8 and 9 verify that low optical absorption SiN, needed for phase-shift mask application, can be maintained over a broad process range by dual ion beam deposition, because the depositing fluxes of Si and N can be controlled independently with individual sources. When a single source (Examples 6 and 8) was used for both Si and N fluxes there is only a narrow range of operating conditions that produce silicon nitride films with attractive optical properties.

What is claimed is:

1. A dual ion-beam deposition process for preparing an attenuating phase shift photo mask blank capable of producing 180° phase shift at selected lithographic wavelengths less than 400 nanometer, the process comprising:
(a) depositing at least one layer of optically transmitting material and at least one layer of optically absorbing material or a combination thereof, on a substrate, by ion beam sputtering of at least one primary target by ions from a group of gases, and
(b) depositing at least one layer of optically transmitting material and optically absorbing material, or a combination thereof, on the said substrate by a secondary ion beam from an assist source of a group of gases wherein the layer or the layers are formed directly, or by a combination of the gas ions from the assist source and the material deposited from the primary target on to the substrate.

2. A dual ion-beam deposition process for preparing an attenuating embedded phase shift photo mask blank capable of producing 180° phase shift at selected lithographic wavelengths less than 400 nanometer, the process comprising:
(a) depositing at least one layer of optically transmitting material and at least one layer of optically absorbing material or a combination thereof, on a substrate, by ion beam sputtering of a target or targets by ions from a group of gases, and
(b) bombarding the said substrate by a secondary ion beam from an assist source with ions from a group of gases wherein at least one gas is from a group consisting of He, Ne, Ar, Kr, Xe, O₂, CO₂, N₂O, H₂O, N₂, NH₃, F₂, CF₄, CHF₃, CH₄, and C₂H₂.

3. The process of claim 1, wherein the optically transmitting material is selected from the group consisting of,
(a) oxides with optical bandgap energy greater than about 3 eV;
(b) nitrides with optical bandgap energy greater than about 3 eV; and,
(c) fluorides with optical bandgap energy greater than 3 eV.

4. The process of claim 3 wherein the optically transmitting material is selected from the group consisting of:
(a) oxides of Si, Al, Zr, Hf, Ta, or Ge;
(b) nitrides of Al, Si, B, C;
(c) fluorides of Al, Cr, , Mg, Ca, Sr, Ba, La, Ce, Pr, Nd, Pm, Sm, Eu, Gd, Tb, Dy, Ho, Er, Tm, Yb, or Lu and,
(d) carbon with the diamond-like carbon structure.

5. The process of claim 1, wherein the optically absorbing material is selected from the group consisting of elemental metals, the metal oxides and nitrides of group IIIB, IVB, VB, and VIB in the periodic table of elements, and carbon with diamond-like structure.

6. The process of claim 4, wherein the optically transmitting component is selected from group consisting of SiOx, Si₃N_{4-y}, and CrFz, wherein:
x ranges from about 1.5 to about 2,
y ranges from about 0 to about 1, and
z ranges from about 1 to about 3.

7. The process in claim 1, wherein the group of gases is selected from the group consisting of He, Ne, Kr, Ar, Xe, N₂, O₂, CO₂, N₂O, H₂O, NH₃, F₂, CF₄, CHF₃, CH₄, and C₂H₂, and combinations thereof.

8. A photomask blank made as in claim 1, comprising at least one layer of optically absorbing material and one layer of optically transmitting material.

9. A photomask blank made as in claim 1, comprising at least one pair of layers consisting of an alternating layer of optically absorbing material and a layer of optically transmitting material.

10. The photomask blank made as in claim 1, wherein the selected lithographic wavelength is selected from the group consisting of 157 nm, 193 nm, 248 nm, and 365 nm.

11. A single ion-beam deposition process for preparing an attenuating embedded phase shift photo mask blank capable of producing 180° phase shift at selected lithographic wavelengths less than 400 nanometer, the process comprising depositing at least one layer of optically transmitting material and at least one layer of optically absorbing material or a combination thereof, on a substrate, by ion beam sputtering of a target or targets by ions from a group of gases.

12. The process of claim 11, wherein the optically transmitting material is selected from the group consisting of:
(a) oxides with optical bandgap energy greater than about 3 eV;
(b) nitrides with optical bandgap energy greater than about 3 eV ; and,
(c) fluorides with optical bandgap energy greater than 3 eV.

13. The process of claim 12, wherein the optically transmitting material is selected from the group consisting of:
(a) oxides of Hf, , Zr, Ta, Al, Si, or Ge;
(b) nitrides of Al, Si, B, C; and,
(c) fluorides of Al, Cr, , Mg, Ca, Sr, Ba, La, Ce, Pr, Nd, Pm, Sm, Eu, Gd, Tb, Dy, Ho, Er, Tm, Yb, or Lu;
(d) carbon with the diamond-like carbon structure.

14. The process of claim 11, wherein the optically absorbing material is selected from the group consisting of: elemental metals, and the metal oxides and nitrides of group IIIB, IVB, VB, and VIB in the periodic table of elements and carbon with diamond-like structure.

15. The process of claim 11, wherein the optically transmitting component is selected from group consisting of SiOx, Si₃N_{4-y}, or CrFz, wherein:
x=1.5 to 2,
y=0 to 1, and
z=1 to 3.

16. The process in claim 10, wherein the group of gases is selected from the group consisting of He, Ne, Kr, Ar, Xe, N₂, O₂, CO₂, F₂. N₂O, H₂O, NH₃, CF₄, CHF₃, CH₄, and C₂H₂ and combinations thereof.

17. A photomask blank made as in claim 11, comprising at least one layer of optically absorbing material and one layer of optically transmitting material.

18. A photomask blank made as in claim 11, comprising at least one pair layers consisting of an alternating layer of optically absorbing material and a layer of optically transmitting material.

19. The photomask blank made as in claim 11, wherein the selected lithographic wavelength is selected from the group consisting of 157 nm, 193 nm, 248 nm, and 365 nm.
